(19) United States
(12) Patent Application Publication
(10) Pub. No.: US 2008/0113484 A1
(43) Pub. Date: May 15, 2008

(54) METHOD OF MANUFACTURING SEMICONDUCTOR DEVICE

(75) Inventor: Takae SUKEGAWA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/847,587

(22) Filed: Aug. 30, 2007

(30) Foreign Application Priority Data
Nov. 10, 2006 (JP) 2006-305678

(51) Int. Cl. H01L 21/20

(52) U.S. Cl. 438/424; 257/E21.553

(57) ABSTRACT

When an isolation insulating film is formed, first, by thermal oxidation method, a silicon oxide film having a thickness of about 5 nm is formed. Next, a silicon nitride film having a thickness of about 3 nm to about 20 nm is formed. The silicon oxide film and the silicon nitride film serve as a liner film. When the silicon nitride film is formed, BTBAS is used as a growth gas, and NH₃ gas is also supplied. As for conditions, the temperature of the substrate is set to be 600° C. or lower, the pressure inside the chamber is set to be 200 Pa or lower, and the flow rate of BTBAS and NH₃ (NH₃/BTBAS) is set to be 0.1 to 30. After forming the silicon nitride film, the silicon oxide film is formed by a high density plasma method. Then, it is flattened using a CMP method or the like.

### CROSS-REFERENCE TO RELATED APPLICATIONS

This application is based upon and claims the benefit of priority from the prior Japanese Patent Application No. 2006-305678, filed on Nov. 10, 2006, the entire contents of which are incorporated herein by reference.

### BACKGROUND OF THE INVENTION

1. Field of the Invention

The present invention relates to a method of manufacturing a semiconductor device which plans to activate an impurity highly.

2. Description of the Related Art

When a field-effect transistor or the like is formed, activation of an impurity doped in the impurity diffusion region such as an extension region or the like is performed. When the activation is performed, rapid lamp heating using a halogen lamp is conducted.

In recent years, a demand for miniaturization of semiconductor devices has been increasing. Accordingly, reduction of contact resistance, and shallow junction and abrupt impurity profile in the impurity diffusion region have been required. In such circumstances, flash lamp annealing (FLA) using a xenon (Xe) lamp (wavelength: 200 nm to 1000 nm) has attracted public attention, which is capable of processing at a higher temperature in a shorter time compared with the conventional rapid lamp heating.

The xenon (Xe) flash lamp is an apparatus having xenon (Xe) gas enclosed in a tube such as a quartz tube or the like. It has the capability of generating white light in a short space of time, for instance, about several hundreds ms to about several hundreds ns by discharging electric charge stored in a capacitor or the like. By applying flash lamp light, it is possible to conduct non-equilibrium heat processing in an ultra-short time in the range of submillisecond. Therefore, high electric activation can be realized, which overcomes the solubility limit of the impurity in relation to the temperature by conventional technologies. Furthermore, it is possible to obtain an abrupt impurity profile.

In FLA, however, since the temperature of the whole surface of the semiconductor substrate is raised and lowered instantly, a large and steep temperature gradient occurs in relation to depth within the semiconductor substrate. As a result, the amount of strain largely differs between the front and back surfaces of the semiconductor substrate. Especially, when gate electrodes or the like are formed, a number of reflections occur on the surface side, which raises the surface temperature easily. Then, the semiconductor substrate is bent so that it protrudes towards the back surface in a U-shape, and line defects (dislocation) and plane defects (slip) etc., occur.

Once a U-shaped curve is generated on the semiconductor substrate, difficulties may occur in the subsequent processes. For instance, the semiconductor substrate is sometimes carried in an adsorbed state created by a vacuum chuck. Under such a circumstance, adsorption defects may occur. In addition, since a difference in height between the central and the periphery has been generated, it may easily cause displacement at the time of exposure of a photosensitive film or the like.

Due to these factors, the yield of a semiconductor device is reduced. This problem becomes more remarkable as the semiconductor substrate increases in diameter thereof.

It is possible to reduce the above-described strain by lowering a preliminary heating temperature of the semiconductor substrate before exposure of light or by lowering irradiation energy of the xenon (Xe) flash lamp, but activation of the impurity cannot be sufficient.

A related art is disclosed in Japanese Patent Application Laid-open No. 2004-152888.

### SUMMARY OF THE INVENTION

An object of the present invention is to provide a method of manufacturing a semiconductor device that is capable of activating the impurity more with suppressing the bending of the semiconductor device.

As a result of earnest studies to solve the above-described problems, the present inventor has come up with the invention shown below.

In a method of manufacturing the semiconductor device according to the present invention, a trench is formed on a surface of a semiconductor substrate, and then, an isolation insulating film is formed in the trench. Next, an impurity is introduced into an element activating region defined by the trench. Then, the impurity is activated by heating the surface of the semiconductor substrate. A silicon nitride film is formed as a liner film when the isolation insulating film is formed.

### BRIEF DESCRIPTION OF THE DRAWINGS

FIGS. 1A to 1C are cross sections showing an outline of experiments in process order;

FIG. 2A is a graph showing a result of an experiment (thickness of the silicon nitride film: 20 nm);

FIG. 2B is a graph showing a result of another experiment (thickness of the silicon nitride film: 80 nm);

FIG. 3 is a graph showing a relation between presence or absence of a silicon nitride film on a back side and degrees of bending;

FIG. 4 is a graph showing a relation between conditions of liner film formation and types and degrees of bending of substrates;

FIGS. 5A to 5G are cross sections showing a method of manufacturing a semiconductor device according to an embodiment of the present invention in process order;

FIG. 6 is a view showing a detail of an isolation insulating film 6.

### DETAILED DESCRIPTION OF THE PREFERRED EMBODIMENTS

—Basic Gist of the Present Invention—

The basic gist of the present invention will be explained first. In a conventional manufacturing method of a semiconductor device, when an isolation insulating film is formed by a shallow trench isolation (STI) method, a thin silicon nitride film is formed on the side and the bottom of a trench as a liner film. Tetraethoxysilane (TEOS) or dichlorosilane (DCS) is used as a raw material for the silicon nitride film. It should be noted that the liner film is formed for keeping a mobility of electric charge high by affecting tensile stress on a channel. It has also a function to control a shape near the boundary between the isolation insulating film and the element activating region. The silicon nitride film itself is a transparent film to the light from the xenon (Xe) flash lamp, but a silicon substrate located directly under thereof serves as an absorbent, and the temperature of the silicon nitride film is raised as well as that of the silicon substrate temperature. Because of the above-described reason, it is understood from inspection by the inventor that a conventional method creates a bending of the semiconductor substrate. Therefore, it is conceivable that if a silicon nitride film as a liner film is formed using a material having a lower heat shrinkage ratio, it is possible to reduce the bending of the semiconductor substrate.

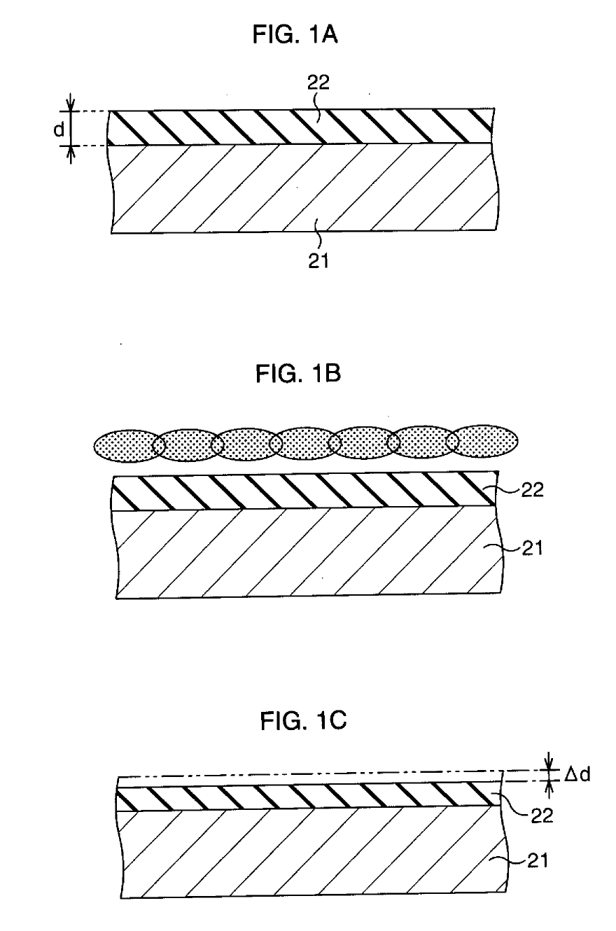

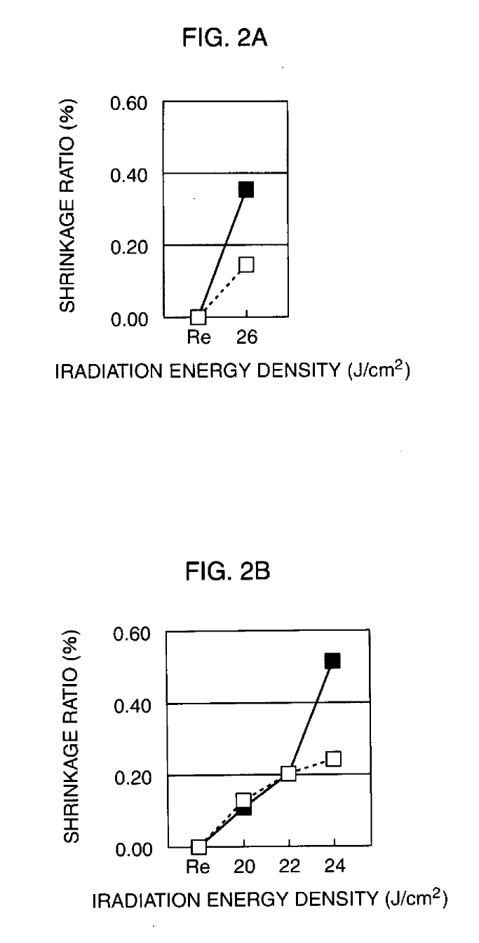

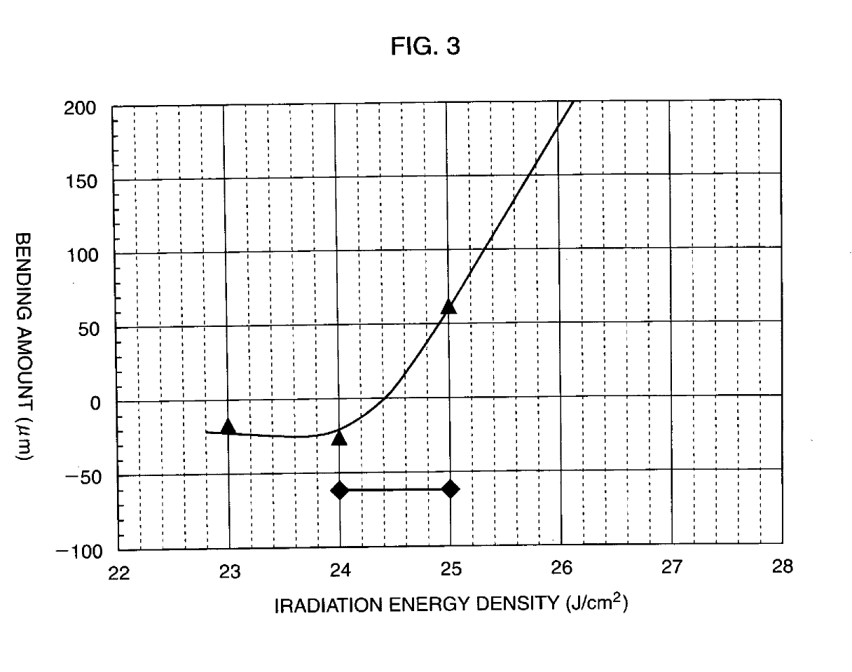

As a result of experiments conducted by the present inventor based on such a point of view using various materials, it has been found that bis(tertiarybutylamino)silane (BTBAS) is useful in FLA using a xenon (Xe) flash lamp. FIGS. 1A to 1C are views showing an outline of experiments performed by the present inventor, and FIGS. 2A and 2B are the graphs showing results.

In this experiment, as shown in FIG. 1A, a silicon nitride film 22 having a thickness of d was formed on a silicon substrate 21. As a raw material of the silicon nitride film 22, dichlorosilane (DCS) or bis(tertiarybutylamino)silane (BTBAS) was used. Next, as shown in FIG. 1B, FLA was conducted to the silicon substrate 21 and the silicon nitride film 22 using the xenon (Xe) flash lamp. As a result, as shown in FIG. 1C, the silicon nitride film 22 was shrunken to reduce the thickness. The thickness decrease Δd was measured, and “Δd/d×100” was calculated as the rate of shrinkage. Results are shown in FIGS. 2A and 2B. FIG. 2A shows a result when the thickness of the silicon nitride film 22 was 20 nm, and FIG. 2B shows a result when the thickness of the silicon nitride film 22 was 80 nm. The black squares ▪ in FIGS. 2A and 2B shows a result obtained when DCS was used, and a white square □ shows a result obtained when BTBAS was used. “Re” indicates reference data when FLA was not conducted (irradiation energy density: 0 J/cm²) and the shrinkage ratio thereof was naturally 0%.

As shown in FIGS. 2A and 2B, when BTBAS was used, the shrinkage ratio was lowered. This means that when BTBAS is used, even when the surface of the silicon substrate is heated to higher temperatures by heat irradiation which has a higher energy density, there is great difficulty in bending the silicon substrate. In other words, it is possible to suppress bending of the silicon substrate with activating the impurity more strongly.

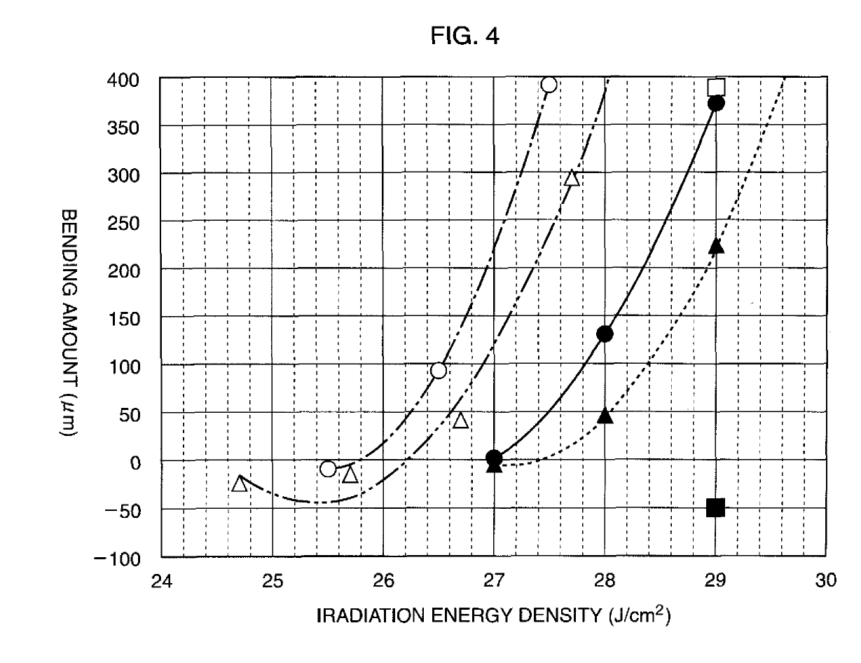

It has been found from another experiment by the present inventor that it is also effective to form a film such as a silicon nitride film or the like which applies a tensile stress on the back of the semiconductor substrate. In this experiment, the degree of bending when FLA was conducted to the silicon substrate, and when FLA was conducted to a silicon substrate on which a silicon nitride film was formed on the back thereof were measured. The results are shown in FIG. 3. A black rhombus ♦ shows when the silicon nitride film is present, and a black triangle ▴ shows when it is absent.

As shown in FIG. 3, it has been found that the degree of bending is smaller when the silicon nitride film is formed on the back. As for the conditions of FLA, the held substrate temperature was set to 450° C. and ½ pulse width of the flash lamp light (pulse light) was set to 0.8 ms.

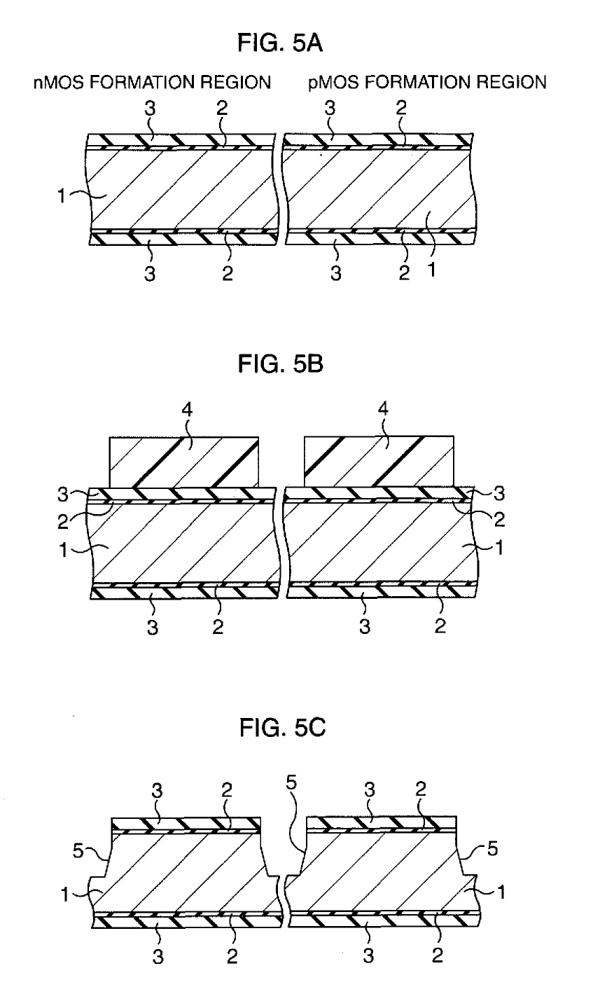

Furthermore, the present inventor conducted FLA with changing raw materials of the silicon nitride film as a liner, structures on the surface of the silicon substrate and types of the silicon substrate, and measured degrees of bending. The results are shown in FIG. 4. As for the conditions of FLA, the substrate temperature was set to 450° C. and ½ pulse width of the flash lamp light (pulse light) was set to 0.8 ms.

In FIG. 4, a white round ◯ shows results obtained by forming a liner film on an epitaxial substrate using DCS and a first structure is formed on the surface of the epitaxial substrate. A white triangle Δ shows results obtained by forming the liner film on the epitaxial substrate using DCS and forming a second structure on the surface of the epitaxial substrate. In other words, they show results corresponding to those obtained using the conventional technology. Note that ratios of the isolation insulating region differ between the first structure and the second structure.

In FIG. 4, a black round shows results obtained by forming the liner film on the epitaxial substrate using BTBAS and forming the first structure on the surface of the epitaxial substrate. A black triangle ▴ shows results obtained by forming the liner film on the epitaxial substrate using BTBAS and forming the second structure on the surface of the epitaxial substrate.

In FIG. 4, a white square □ shows results obtained by forming the liner film on the epitaxial substrate using BTBAS and forming a third structure on the surface of the epitaxial substrate. A black square ▪ shows results obtained by forming the liner film on a Czochralski (CZ) substrate using BTBAS and forming the third structure on the surface of the epitaxial substrate. Note that ratios of the isolation insulating region or the like differ between the first and second structures and the third structure.

In the epitaxial substrate, the epitaxial layer is formed on the doped layer, and the thickness of the doped layer is 99% or more of the whole. The whole resistivity of a conventional epitaxial substrate is 0.02 Ω·cm or lower. On the contrary, the whole resistivity of the CZ substrate is 5 Ω·cm or higher.

As shown in FIG. 4, when the results (◯, ) of the samples with the first structure are compared, it has been found that the irradiation energy density between the samples with similar degrees of bending is higher in the sample () using BTBAS. When the results (Δ, ▴) of the samples with the second structure are compared, it has been found that the irradiation energy density between the samples with similar degrees of bending is higher in the sample (▴) using BTBAS. From these results, it can be said that it is possible to raise the temperature of the silicon substrate to a higher temperature within an allowable degree of bending by using BTBAS.

As shown in FIG. 4, when the results (□, ▪) of the samples with the third structure are compared, it has been found that the degree of bending caused by irradiation with the same energy density is lower in the sample (▪) using the CZ substrate having high resistivity. Furthermore, when the tendency is considered in other samples, it is considered that the irradiation energy density among the samples with the same degree of bending will be higher in the sample (▪) using a substrate having high resistivity. In other words, it is considered that the higher the resistivity, the greater the degree of bending of the substrate is suppressed. From the experiments conducted by the present inventor, it has been found to be more effective to use a substrate having a resistivity of 0.28 Ω·cm or higher.

### Embodiment of the Present Invention

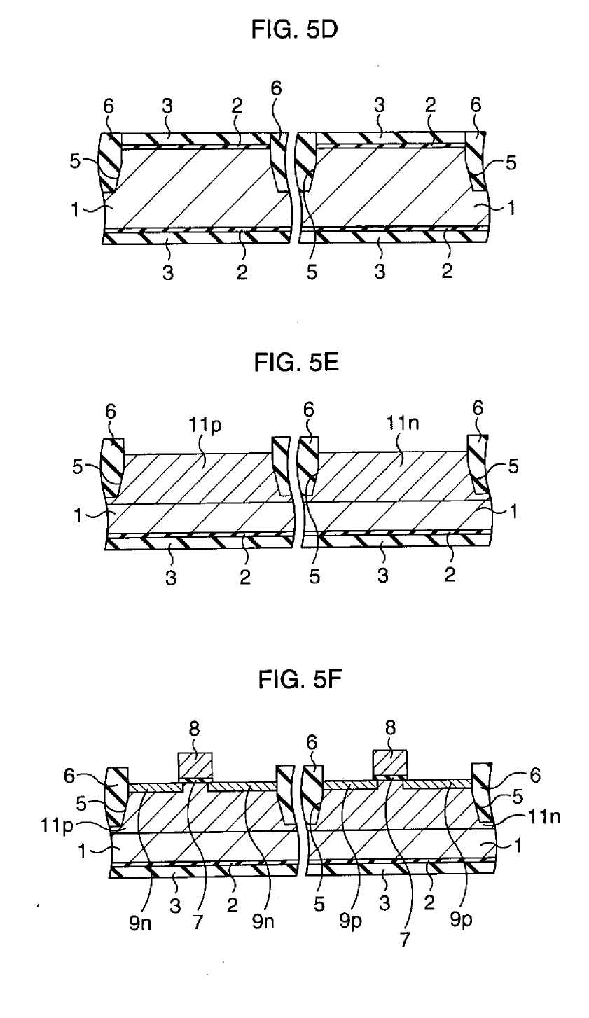

Hereinafter, the embodiment of the present invention will be explained specifically with reference to the attached drawings. FIGS. 5A to 5G are cross sectional views showing a method of manufacturing a semiconductor device according to the embodiment of the present invention in process order. Note that in the present embodiment, an n-channel MOS transistor and a p-channel MOS transistor are formed in parallel. That is, a CMOS transistor is formed.

In the present embodiment, as shown in FIG. 5A, a silicon oxide film 2 and a silicon nitride film 3 are formed in sequence on the front and back surfaces of a silicon substrate 1. As the silicon substrate 1, for instance, an epitaxial substrate having the whole resistivity of more than 0.02 Ω·cm is used. Especially, the epitaxial substrate having resistivity of 0.28 Ω·cm or higher is preferable. This is because that it is considered that the higher the resistivity, the lower the degree of bending, as described above. As for the silicon oxide film 2, for instance, a thermal oxidation film is formed. The silicon nitride film 3 is formed by a CVD method using, for instance, a vertical furnace. The thickness of the silicon nitride film 3 is about 70 nm to about 150 nm.

Next, as shown in FIG. 5B, a resist pattern 4 is formed on the silicon nitride film 3 on the front surface side of the silicon substrate 1. When the resist pattern 4 is formed, openings are made in areas to form an isolation insulating region, by applying photosensitive resist and by conducting exposure and development thereto.

Next, as shown in FIG. 5C, dry etching of the silicone nitride film 3 on the front surface side is conducted with using the resist pattern 4 as a mask. Thereafter, the resist pattern 4 is removed. Then, dry etching of the silicon oxide film 2 and the silicon substrate 1 on the front surface side is conducted with using the silicon nitride film 3 as a mask so as to form a trench 5 for element separation.

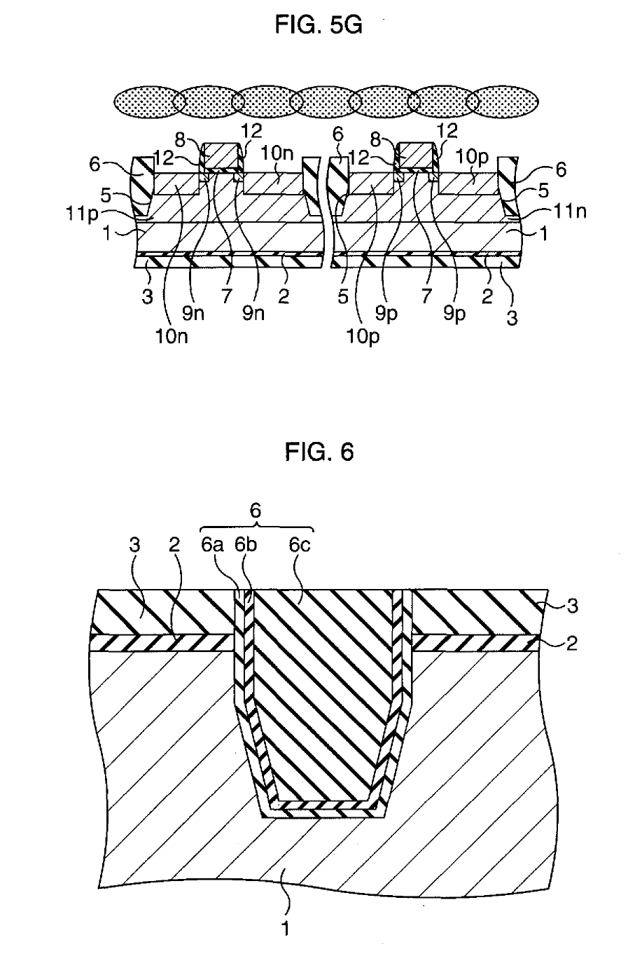

Thereafter, as shown in FIG. 5D, an isolation insulating film 6 is formed in the trench 5. When the isolation insulating film 6 is formed, as shown in FIG. 6, a silicon oxide film 6a having a thickness of about 5 nm is formed by a thermal oxidation method first. Then, a silicon nitride film 6b having a thickness of about 3 nm to about 20 nm by a CVD method, for instance. The silicon oxide film 6a and the silicon nitride film 6b serve as a liner film. Note that when the silicon nitride film 6b is formed, BTBAS is used as a growth gas, and NH₃ gas is also supplied. For instance, the temperature of the substrate is set to be 600° C. or lower, the pressure inside the chamber is set to be 200 Pa or lower, and the flow rate of BTBAS and NH₃ (NH₃/BTBAS) is set to be 0.1 to 30. After the silicon nitride film 6b is formed, a silicon oxide film 6c is formed by a high-density-plasma (HDP) method. Then, it is flattened until the silicon nitride film 3 is exposed using a CMP method or the like. Note that a spin-on-glass (SOG) oxide film or the like may be formed as the silicon oxide film 6c.

Next, as shown in FIG. 5E, the silicon nitride film 3 and the silicon oxide film 2 on the front surface side are removed. Then, an n-well 11n is formed by performing ion implantation of an n-type impurity into the silicon substrate 1 in a pMOS formation region (region designed to form a p-channel MOS transistor), which is one of the element activating regions defined by the isolation insulating film 6. Further, a p-well lip is formed by performing ion implantation of a p-type impurity into the silicon substrate 1 in an nMOS formation region (region designed to form an n-channel MOS transistor), which is other one of the element activating regions defined by the isolation insulating film 6. Furthermore, in order to control the threshold voltage of a transistor to be formed, ion implantation of impurities to the n-well 11n and the p-well 11p may be conducted.

Next, an isolating film of a silicon oxide film or the like is formed on the surface of the silicon substrate 1, and a conductive film of polycrystalline silicon film or the like is formed thereon. By patterning these films, a gate isolating film 7 and a gate electrode 8 are formed as shown in FIG. 5F. Thereafter, p-type extension regions 9p are formed by conducting ion-implantation of a p-type impurity shallowly into the pMOS formation region with using the gate electrode 8 as a mask. Furthermore, n-type extension regions 9n are formed by conducting ion-implantation of a n-type impurity shallowly into the nMOS formation region with using the gate electrode 8 as a mask.

Then, as shown in FIG. 5G, sidewall isolating films 12 are formed on the sides of the gate electrodes 8. When the side wall isolating films 12 are formed, for instance, a silicon oxide film is formed first. A silicon nitride film is formed on the silicon oxide film, and etch back for these films is conducted. When the silicon nitride film is formed, BTBAS is used as a growth gas, and NH₃ gas is also supplied. As for the conditions, for instance, the temperature of the substrate is set to be 600° C. or below, the pressure inside the chamber is set to be 200 Pa or lower, and the flow rate of BTBAS and NH₃ (NH₃/BTBAS) is set to be 0.1 to 30. In short, it is preferable to use the same condition as the condition to form the silicon nitride film 6b.

After forming the sidewall isolating films 12, deep p-type SD regions (source/drain regions) 10p are formed by ion-implanting a p-type impurity deeply into the pMOS formation region with using the gate electrode 8 and the sidewall isolating film 12 as a mask. As a result, source/drain diffusion layers provided with the p-type extension region 9p and the p-type SD region 10p are formed in the pMOS formation region. Further, deep n-type SD regions (source/drain regions) 10n are formed by ion-implanting an n-type impurity deeply into the nMOS formation region with using the gate electrode 8 and the sidewall isolating film 12 as a mask. As a result, source/drain diffusion layers provided with the n-type extension region 9n and the n-type SD region 10n are formed in the nMOS formation region.

Next, the impurity implanted in the respective source/drain diffusion layers are activated. FLA using a xenon (Xe) flash lamp is conducted in this activation. As for the conditions of FLA, for example, the preliminary heating temperature of the silicon substrate 1 is set to be about 450° C., the irradiation energy density is about 29 J/cm², and a ½ pulse width of a flash lamp light (pulse light) is 0.8 msec. Under such conditions, the maximum reachable temperature on the front surface side is 1300° C. or higher.

Then, by conducting formation of interlayer isolating films, formation of contact plugs, and formation of wirings and the like, a semiconductor device is completed.

By a conventional method, when the semiconductor device is heated to 1300° C. or higher using the xenon (Xe) flash lamp, the silicon substrate 1 is bent into a deep “U” shape. In particular, a silicon substrate with small surface reflectance generates a bend even at 1250° C. or higher. On the contrary, in the present embodiment, since the silicon nitride film 6b is formed as a portion of the liner film using BTBAS, it is possible to suppress such a bend. The effect to suppress such a bend can be made remarkable by using the silicon substrate 1 having the resistivity of 0.28 Ω·cm or more and formation of the silicon nitride film 3 on the back face side. Furthermore, according to the present embodiment, it is possible to suppress the bend during FLA, which makes it possible to raise the temperature to a degree higher than that by a conventional method. Therefore, the impurity can be activated more. This effect is more remarkable especially when a semiconductor substrate having a diameter of 200 mm or more is used.

It should be noted that a CZ substrate or the like can be used as the silicon substrate 1. The resistivity of the CZ substrate is about 5 Ω·cm. Furthermore, it is preferable that the pulse width of the xenon flash lamp light is made to 0.5 msec to 2 msec. The reason is because when it is less than 0.5 msec, sometimes sufficient heating cannot be performed, and when it exceeds 2 msec, it results in excessive heating and sometimes the impurity profile becomes gentle. Furthermore, it is preferable that the irradiation energy density of the pulse light is 20 J/cm² to 34 J/cm². The reason is because when it is less than 20 J/cm², sometimes sufficient heating cannot be performed, and when it exceeds 34 J/cm², it results in excess heating and sometimes the impurity concentration profile becomes gentle.

A certain document describes that aiming at reducing the bend of the semiconductor device during RTA, a high resistant substrate is used. No description, however, is found about the raw material for the liner film. In addition, since the semiconductor substrate is heated as a whole during RTA, there is no connection to the bend originated from the temperature gradient from the beginning.

Another document mentions adjustment of the pulselength, aiming at suppressing damage to the crystal during annealing using a pulse laser. No description, however, is found discussing the raw material for the liner film. Furthermore, with this technology, a long time is required to retain the system at a maximum temperature, which makes the impurity concentration profile gentle.

When an isolation insulating film is formed, since a silicon nitride film is formed as a liner film using bis(tertiallybutylamino)silane, for example, as a raw material gas according to the present invention, the semiconductor substrate is not likely to be bent during the following heating as described above. Therefore, it is possible to make the impurity highly activated by setting the maximum temperature to be high during heating to activate the impurity.

The present embodiments are to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

What is claimed is:

1. A method of manufacturing a semiconductor device, comprising the steps of:
forming a trench on a surface of a semiconductor substrate;
forming an isolation insulating film in said trench, the step of forming said isolation insulating film including the step of forming a silicon nitride film as a liner film;
introducing an impurity into an element activating region defined by said trench; and
activating said impurity by heating the surface of said semiconductor substrate.

2. The method of manufacturing a semiconductor device according to claim 1, wherein a thickness of said silicon nitride film is set to be 3 nm to 20 nm.

3. The method of manufacturing a semiconductor device according to claim 1, wherein said silicon nitride film is formed with using bis(tertiarybutylamino)silane as a raw material gas.

4. The method of manufacturing a semiconductor device according to claim 1, wherein the step of activating said impurity comprises the step of irradiating a pulse light having a pulse width of 0.5 msec to 2 msec on the surface of said semiconductor substrate.

5. The method of manufacturing a semiconductor device according to claim 4, wherein a light having a wavelength of 200 nm to 1000 nm is used as said pulse light.

6. The method of manufacturing a semiconductor device according to claim 4, wherein a xenon flash lamp is used as said pulse light.

7. The method of manufacturing a semiconductor device according to claim 4, wherein irradiation energy density of said pulse light is set to be 20 J/cm² to 34 J/cm².

8. The method of manufacturing a semiconductor device according to claim 1, further comprising the step of, before the step of activating said impurity, forming a film suppressing bending of said semiconductor substrate during activating said impurity on a back face of said semiconductor substrate.

9. The method of manufacturing a semiconductor device according to claim 8, wherein a silicon nitride film is formed as said film suppressing bending of said semiconductor substrate.

10. The method of manufacturing a semiconductor device according to claim 9, wherein the step of forming said trench comprises the steps of:
forming a silicon nitride film for a mask on a surface of said semiconductor substrate at the same time of formation of said silicon nitride film suppressing bending of said semiconductor substrate;
patterning said silicon nitride film for a mask; and
performing dry etching of said semiconductor substrate with using said silicon nitride film for a mask as the mask.

11. The method of manufacturing a semiconductor device according to claim 1, wherein a CZ substrate formed by a Czochralski method is used as said semiconductor substrate.

12. The method of manufacturing a semiconductor device according to claim 1, wherein an epitaxial substrate including a dope layer and an epitaxial layer formed thereon and having a whole resistivity of 0.28 Ω·cm or more is used as said semiconductor substrate.

13. The method of manufacturing a semiconductor device according to claim 12, wherein an epitaxial substrate having a dope layer whose resistivity is 0.20 Ω·cm or more is used as said epitaxial substrate.

14. The method of manufacturing a semiconductor device according to claim 12, wherein an epitaxial substrate having a dope layer whose resistivity is 10 Ω·cm or more is used as said epitaxial substrate.

15. The method of manufacturing a semiconductor device according to claim 1, further comprising the step of, between the step of forming said isolation insulating film and the step of introducing said impurity, forming a gate isolating film and a gate electrode in said element activating region.

16. The method of manufacturing a semiconductor device according to claim 15, further comprising the steps of, after the step of forming said gate electrode:
forming a second silicon nitride film on a side of said gate electrode with using bis(tertiarybutylamino)silane as a raw material gas; and
performing etch back of said second silicon nitride film.

17. The method of manufacturing a semiconductor device according to claim 1, wherein a substrate having a diameter of 200 mm or more is used as said semiconductor substrate.
